(19) United States
(12) Patent Application Publication
(10) Pub. No.: US 2008/0217052 A1
(43) Pub. Date: Sep. 11, 2008

(54) WIRING BOARD AND METHOD OF MANUFACTURING WIRING BOARD

(75) Inventor: Akiko MATSUI, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 12/043,432

(22) Filed: Mar. 6, 2008

(30) Foreign Application Priority Data
Mar. 7, 2007 (JP) 2007-057827

(51) Int. Cl. H05K 1/11; H05K 3/02

(52) U.S. Cl. 174/266; 29/846

(57) ABSTRACT

A wiring board including a plated through hole formed in the wiring board; a test plated through hole or a test via hole provided in the surrounding area of the plated through hole to check a processing state related to the plated through hole; and a conductive pattern used to electrically connect the plated through hole to the test through hole or the test via hole.

### CROSS REFERENCE TO RELATED APPLICATIONS

This application is related to and claims priority to Japanese Patent Application No. JP 2007-057827 filed on Jul. 3, 2007 in the Japan Patent Office, and incorporated by reference herein.

### BACKGROUND

1. Field

The embodiment relates to a wiring board. The embodiment is favorably adapted to a wiring board having a plated through hole connected to a conductive layer including a signal wiring.

2. Description of the Related Art

A multi-layer wiring board is employed as a wiring board so as to form a high-frequency circuit and a high-speed digital circuit and the like. The multi-layer wiring board includes a plated through hole so as to pull out the conductive layer including the signal wiring formed in the multi-layer wiring board to the surface of the board.

In FIG. 1, a wiring board 1 is a multi-layer wiring board. A signal wiring 2 is formed with a conductive layer formed in the multi-layer wiring board. A plated thorough hole 3 is formed so as to be electrically connected to the signal wiring 2 in the wiring board 1. The plated through hole 3 is formed by plating a conductive material such as copper onto the inner wall of a non-plated through hole.

The signal wiring 2 is electrically connected to the plated through hole 3 by connecting to the plated through hole 3 near the center of the plated through hole 3. The plated through hole 3 is formed in the wiring board 1 so as to pull out the signal wiring 2 to the surface of the wiring board 1. An electronic signal is provided from the surface of the plated through hole 3, and is transmitted to the signal wiring 2 near the center of the plated through hole 3. The part where the signal wiring 2 is connected becomes a branch point of signal paths because the plated through hole 3 is extended below the part where the signal wiring 2 is connected.

Signals transmitted through the plated through hole 3 are transmitted to the signal wiring 2 from the branch point, and some of the signals are also transmitted down below the plated through hole 3. The downside of the branch point in the plated through hole 3 is a path in which signals are transmitted because the downside of the branch point is a conductive part, even though the downside of the branch point is not a signal path. As described above, in case a signal path is branched into two, the part which is not an original signal path is referred to as “stub”.

A signal transmitted to a stub from the branch point is reflected at the bottom of the plated through hole 3, and is then returned to the branch point. At that time, the signal transmitting from the branch point hits the reflected signal in the plated through hole. This may adversely affect a transmission characteristic of the signals. For example, signals such as high-frequency signals and high-speed digital signals are affected significantly.

For example, Japanese Laid-open Patent Publication No. 2005-116945 is known as a method for removing a stub. Japanese Laid-open Patent Publication No. 2005-116945 discloses a technology for removing a plated through hole and a board nearby by drilling. Such technology may be referred to as “back drilled method” or “stub countersunk method”.

In the back-drilled method shown in FIGS. 2A-2C, the part where the plated through hole 3 is formed is removed with a drill 4 whose diameter is slightly bigger than the diameter of the plated through hole 3. As a result, the part corresponding to a stub in the plated through hole 3 is removed. The hole formed with the drill 4 is referred to as “back-drilled hole”. FIG. 2A shows that the plated through hole 3 is formed. FIG. 2B shows the process of drilling the plated through hole 3 with the drill 4. FIG. 2C shows that a back-drilled hole 5 is formed by drilling the plated through hole 3.

However, if the central axis of the drill is positioned out of the central axis of the plated through hole, there is possibility that the part corresponding to a stub in the plated through hole remains even after the back-drilled processing. By checking the back-drilled hole visually, it is possible to determine whether or not the part corresponding to a stub in the plated through hole is completely removed. However, the determination is not made easily if the diameter of the plated through hole is small.

### SUMMARY

It is an object of the embodiment to at least partially solve the problem in the conventional technology.

According to an aspect of an embodiment, a wiring board, comprising: a plated through hole formed in the wiring board; a test plated through hole or a test via hole provided in the surrounding area of the plated through hole to check a processing state related to the plated through hole; and a conductive pattern used to electrically connect the plated through hole to the test through hole or the test via hole.

According to another aspect of the embodiment, a wiring board, comprising: a plated through hole formed in the wiring board; a processing hole formed to remove a part of the plated through hole in the position where the plated through hole is provided; a test plated through hole and a test via hole in the surrounding area of the test plated through hole to check a processing state related to the plated through hole; and a conductive pattern extended between the processing hole where the plated through hole is removed and the test plated through hole or the via hole, and also is electrically connected to the test plated through hole or the test via hole.

According to still another aspect of the embodiment, a method of manufacturing a wiring board, comprising: forming a plated through hole in the wiring board; forming a test plated through hole or a via hole in the wiring board; forming a conductive pattern which is used to electrically connect the plated through hole to the test plated through hole or the test via hole; and forming a processing hole in a position in the wiring board where the plated through hole is located.

The above and other objects, features, advantages and technical and industrial significance of this embodiment will be better understood by reading the following detailed description of presently preferred embodiments, when considered in connection with the accompanying drawings.

### BRIEF DESCRIPTION OF THE DRAWINGS

FIG. 1 is a cross-section diagram of a wiring board in which a plated through hole is formed.

FIGS. 2A-2C are diagrams showing a back-drilled method.

FIG. 3 is a cross-section perspective view of a wiring board.

FIG. 4 is a cross-section diagram showing a wiring board according to a first embodiment before a back-drilled hole is formed.

FIG. 5 is a cross-section diagram showing that a back-drilled hole is formed in a wiring board disclosed in FIG. 4.

FIG. 6A is a cross-section diagram showing that a back-drilled hole is not adequately deep, and FIG. 6B is a cross-section diagram showing that a back-drilled hole is formed outside of a desired position.

FIG. 7 is a cross-section diagram showing a test via hole in a multi-layer wiring board.

FIG. 8 is a plan of a wiring board according to a second embodiment.

FIG. 9 is a diagram showing test plated through holes are closely-allocated when there are a plurality of plated through holes having a stub to remove.

FIG. 10 is a plan of a wiring board according to a third embodiment.

FIG. 11 is a diagram showing an example that one test plated through hole is commonly used when there are a plurality of plated through holes having a stub remove.

FIG. 12 is a plan of a wiring board according to a fourth embodiment.

FIG. 13 is a diagram showing an example that one of the test plated through holes is commonly used by providing a ground layer when there are a plurality of plated through holes having a stub to remove.

### DETAILED DESCRIPTION OF THE PREFERRED EMBODIMENTS

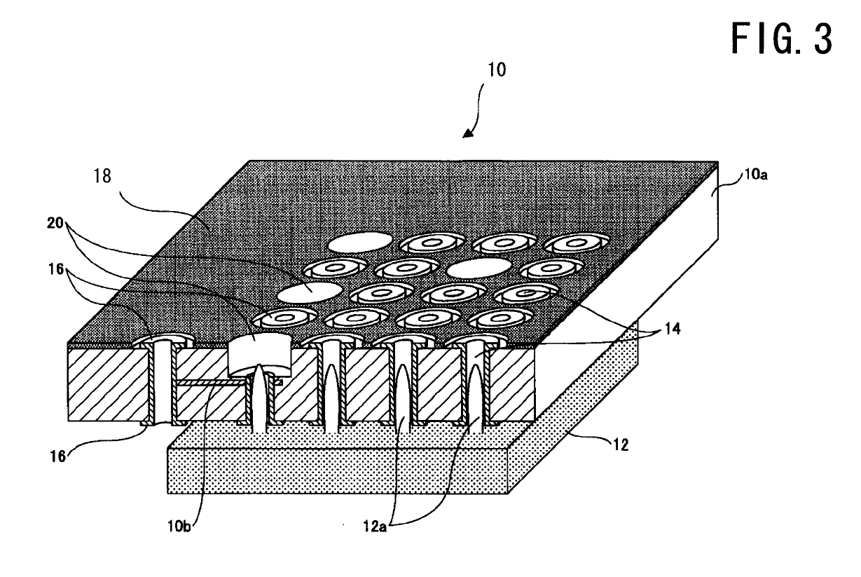

A wiring board of the present embodiment is explained using FIG. 3. FIG. 3 discloses that an electronic component 12 is loaded on a mounting surface of a wiring board 10. The wiring board 10 is comprised of a multi-layer wiring board 10a which is formed by laminating plastic such as glass epoxy and polyimide. A terminal 12a of the electronic component 12 is inserted into a plated through hole 14 formed in the multi-layer wiring board 10a, and is connected to the plated through hole 14 with an electrically conductive adhesive such as a solder. In the multi-layer wiring board 10a, a signal wiring 10b is formed and connected to the plated through hole 14.

The plated through hole 14 is formed by plating a conductive material, such as copper, onto the inner wall of a non-plated through hole formed in the multi-layer wiring board 10a.

A land 16 whose diameter is slightly bigger than the diameter of the plated through hole 14 is formed at both ends of the plated through hole 14. The land 16 is formed both on the mounting surface and the back surface of the wiring board 10, and the plating processing of the plated through hole 14 is performed at the same time.

A solder resist 18 is applied to the back surface of the multi-layer wiring board 10a, leaving the part where the land 16 is exposed. A back-drilled hole 20 is formed so as to remove the part corresponding to a stub in the plated through hole 14 to which the high-frequency signal is transmitted. The back-drilled hole 20 is a processing hole formed by a cutting process using a drill or the like. However, the process is not limited to the process with a drill. Any process is applicable whereby the part of the plated through hole 14 can be removed together with basic materials nearby.

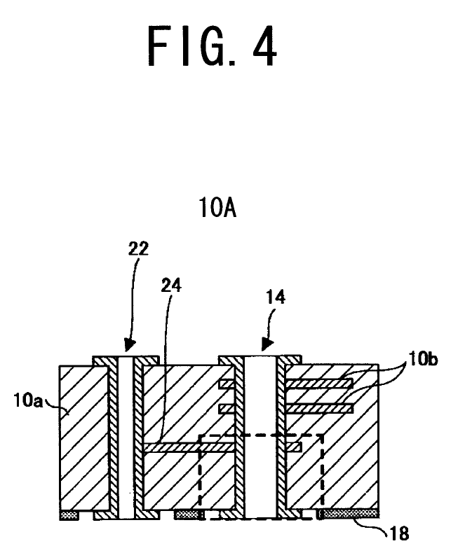

Next, a first embodiment is explained. FIG. 4 discloses the previous state, which is before a back-drilled hole is formed as a processing hole. A wiring board 10A has a test plated through hole or a test via hole near the plated through hole 14 having a stub to remove. The test plated through hole or the test via hole is formed in the multi-layer wiring board 10a, and is electrically connected to the plated though hole 14 having a stub to remove, by a test wiring pattern 24 formed in the multi-layer wiring board 10a comprised of a conductive material pattern. In the present embodiment, a test plated through hole or a test via hole is referred to as “test plated through hole 22”.

The test plated through hole 22 is formed with a diameter which is smaller than the diameter of a normal plated through hole 14. It is preferable that the test plated through hole 22 is smaller than the normal plated through hole 14 because the test plated through hole 22 is used only to test electrical continuity between the plated through hole 14 and the test plated through hole 22.

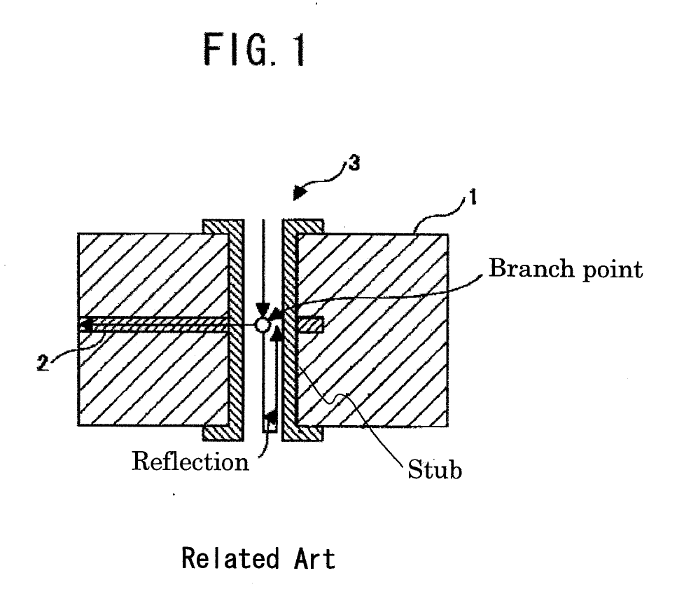

The area encircled with a dotted line in FIG. 4 is the countersunk area where the back-drilled hole 20 is formed by drilling. The test wiring pattern 24 is connected to the plated through hole 14 in the countersunk area. That is, the test wiring pattern 24 is connected to a position close to the branch point in the part corresponding to a stub in the plated through hole 14, as shown in FIG. 1. Due to this, the test plated through hole 22 is electrically connected to the plated through hole 14 by the test wiring pattern 24.

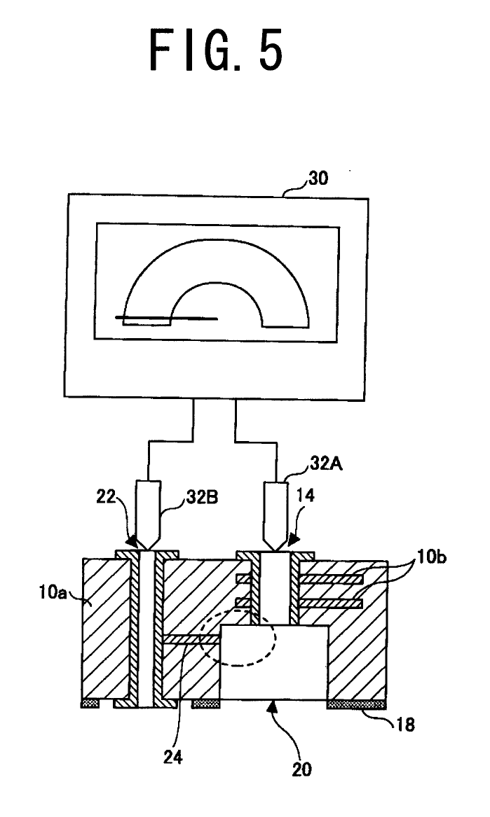

FIG. 5 discloses that the back-drilled hole 20 is formed in the wiring board 10A disclosed in FIG. 4. When forming the back-drilled hole 20 in a correct position, the part corresponding to a stub in the plated through hole 14 is removed by drilling, and the connection point where the test wiring pattern 24 is connected to the plated through hole 14 in the part corresponding to a stub is also removed. Due to this, there is no electrical continuity between the test plated through hole 22 and the plated though hole 14.

As shown in FIG. 5, for example, it is possible to check electrical continuity by measuring electrical resistance between the test plated through hole 22 and the plated through hole 14 when a probe 32A of a tester 30 is contacted by the plated through hole 14 and a probe 32B is contacted by the test plated through hole 22. In the example of FIG. 5, the electrical resistance between the test plated through hole 22 and the plated through hole 14 is remarkably high because the test wiring pattern 24 is disconnected due to the formation of the back-drilled hole 20.

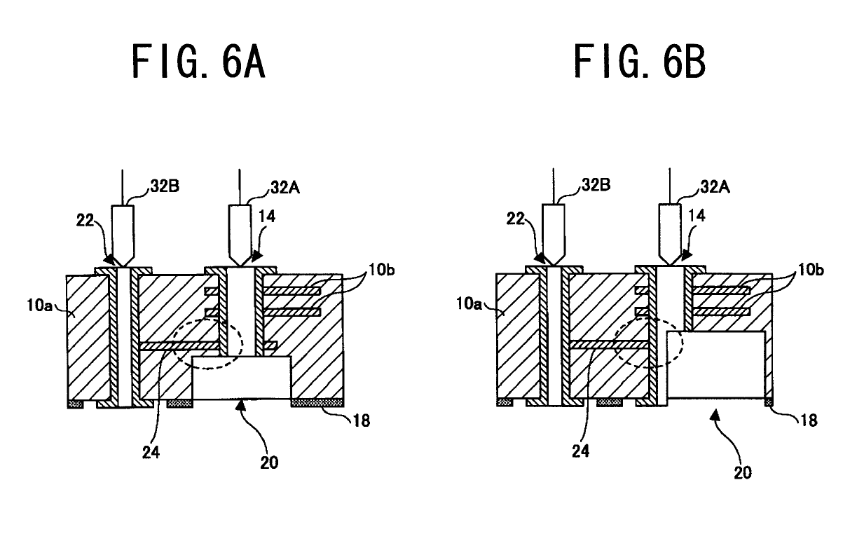

On the other hand, it is not possible to remove the connection point between the test wiring pattern 24 and the plated through hole 14 even if the back-drilled hole 20 is formed when the back-drilled hole 20 is not adequately deep or the back drilled-hole 20 is formed outside of the desired position. FIG. 6A shows that the back-drilled hole 20 is not adequately deep. FIG. 6B shows that the back-drilled hole 20 is formed outside of the desired position.

The example in FIG. 6A shows that the part corresponding to a stub in the plated through hole 14 remains because the back drill is not adequately deep, although the back-drilled hole 20 is correctly positioned at the plated through hole 14. That is, the part corresponding to a stub in the plated through hole 14 is not completely removed because the back drill is shorter than the distance between the surface of the multi-layer wiring board 10a and the test wiring pattern 24.

Therefore, the electrical resistance between the test plated through hole 22 and the plated through hole 14 is remarkably low because the electrical continuity is maintained between the test plated through hole 22 and the plated through hole 14 even after the back-drilled hole 20 is formed.

The example shown in FIG. 6B shows that the part corresponding to a stub in the plated through hole 14 remains because the center of the back-drilled hole 20 is outside of the center of the plated through hole 14 in a direction away from the test plated through hole 22, although the back drill is adequately deep. Therefore, the electrical resistance between the test plated through hole 22 and the plated through hole 14 is remarkably low because the electrical continuity is maintained between the test plated through hole 22 and the plated through hole 14 even after the back-drilled hole 20 is formed.

In the present embodiment, a tester can determine whether or not the part corresponding to a stub is completely removed by checking the electrical continuity between the test plated through hole 22 and the plated through hole 14 after the back-drilled hole 20 is formed by removing the part corresponding to a stub. That is, the tester determines that the part corresponding to a stub is removed if there is no electrical continuity. Also, the tester determines that a bad back-drill occurs because the part corresponding to a stub is not completely removed if there is an electrical continuity. The determination can be made by a simple operation of the tester 30 in a way that the probe 32A is contacted by the test plated through hole 22, and the probe 32B is contacted by the plated through hole 14.

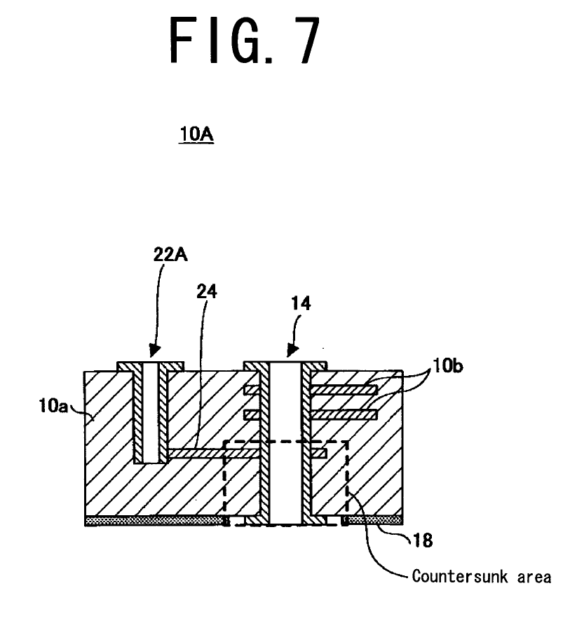

As shown in FIG. 7, although the test plated through hole 22 is passed through the multi-layer wiring board 10a, the test via hole 22A has only to be extended to the position which can be connected to the test wiring pattern 24.

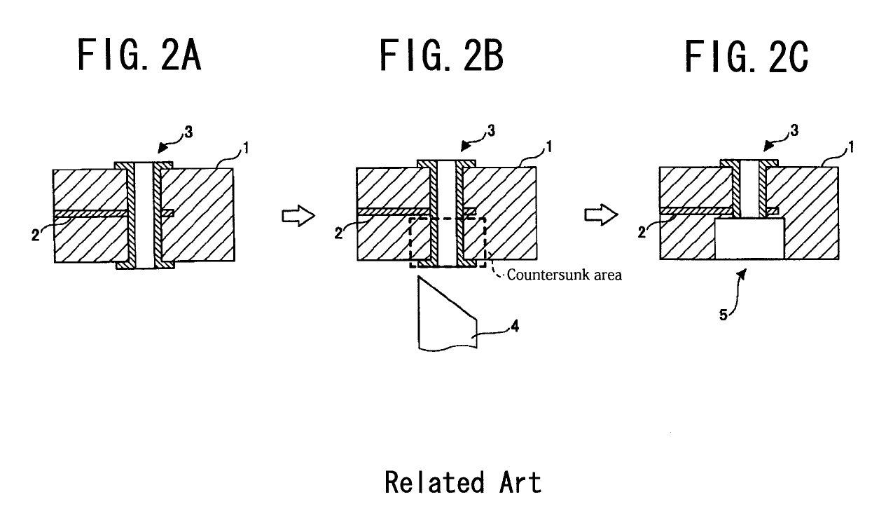

The wiring board 10A can be formed by the same process as the manufacturing process of a normal wiring board. That is, the multi-layer wiring board 10a including the test plated through hole 22 and the test wiring pattern 24 is formed by a well-known manufacturing technology for a multi-layer wiring board. Then, the back-drilled hole 20 is formed in the position where a stub should be removed. For example, the back-drilled hole 20 is formed by the process shown in FIG. 2. The stub should be removed in a plated through hole 14, e.g., a signal path of high-frequency signals or high-speed signals, which may be adversely affected by the existence of a stub. Formation processes of the test plated through hole 22, the test wiring pattern 24 and the back-drilled hole 20 are performed within the manufacturing process of the wiring board 10A.

A testing process is performed to determine whether or not a bad back-drill occurs after the back-drilled hole 20 is formed. In this test, the electrical continuity between the test plated through hole 22 and the plated through hole 14 having a stub to remove is checked by the tester. The test can easily determine whether or not a bad back-drill occurs. That is, the test can determine the removing state of the plated through hole 14 by measuring the electrical resistance between the test plated through hole 22 and the plated though hole 14 having a stub to remove.

As described above, in the present embodiment, the test plated through hole 22 and the test wiring pattern 24 are provided near the plated through hole 14 having a stub to remove. Due to this, the present embodiment can easily determine that the misalignment of the back-drilled hole 20 because the electrical continuity is maintained between the test plated through hole 22 and the plated through hole 14 when the back drill is not adequately deep or when the back-drilled hole 20 is formed outside of the desired position. Therefore, the present embodiment can determine easily that the part of the plated through hole 14, which is corresponding to a stub, remains due to the lack of depth or the misalignment of the back-drilled hole 20, and can properly respond such as restarting a back-drill immediately.

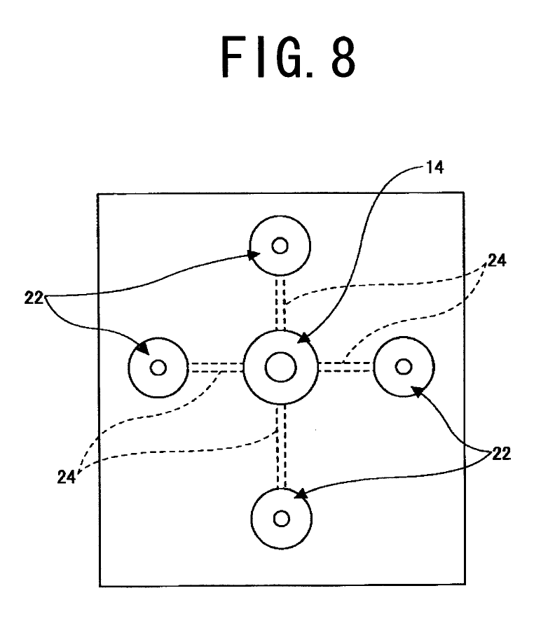

Next, a second embodiment is explained using FIG. 8.

In the first embodiment, the connection point where the test wiring pattern 24 is connected to the plated through hole 14 is not removed when the back-drilled hole 20 is formed outside of the desired position in a direction away from the test plated through hole 22. The first embodiment determines the misalignment of the back-drilled hole 20 by the advantage of having the electrical continuity maintained between the test plated through hole 22 and the plated through hole 14. However, the direction of the misalignment of the back-drilled hole 20 is not limited to a direction away from the test plated through hole 22. The misalignment of the back-drilled hole 20 may be in a direction approaching the test plated through hole 22 or in a perpendicular direction to the test plated through hole 22.

In the present embodiment, the test plated through holes 22 are closely provided in four directions surrounding the plated through hole 14 having a stub to remove. FIG. 8 discloses that four of the test plated through holes 22 are allocated in four directions at angles of 0, 90, 180 and 270 degrees in the surrounding area of the plated through hole 14, centering around the plated through hole 14 having a stub to remove. From each of the test plated through holes 22, the test wiring pattern 24 is extended in a direction toward the plated through hole 14 and is then connected to the plated through hole 14. The test wiring pattern 24 is formed in the multi-layer wiring board 10a, as shown with a dotted line in FIG. 8.

The present embodiment can test the misalignments of the back-drilled hole 20 in four directions at right angles centering around the plated through hole 14. That is, the present embodiment can determine the removing state of the plated through hole 14 by testing the misalignments of the back-drilled hole 20 in almost all directions in the surrounding area of the plated through hole 14.

Of the four test plated through holes 22 shown in FIG. 8, the test plated through hole 22 at downside is allocated farther from the plated through hole 14, compared to the other three test plated through holes 22. Thus, all of the test plated through holes 22 do not have to be allocated at equal distances from the plated through hole 14. The test plated through hole 22 has only to be connected to the plated through hole 14 by the test wiring pattern 24.

A misalignment of the back-drilled hole 20 is determined according to the direction in which the test wiring pattern 24 is connected to the plated through hole 14 and not determined according to the position of the test plated through hole 22. That is, for example, the embodiment in FIG. 8 can test the misalignments of the back-drilled hole 20 in the four directions by the advantage of connecting the test wiring pattern 24 in the four directions around the plated through hole 14. Therefore, the test plated through hole 22 can be allocated at any position in the multi-layer wiring board 10a if the test wiring pattern 24 is formed as a pattern extended to be curved or convoluted, instead of a straight pattern.

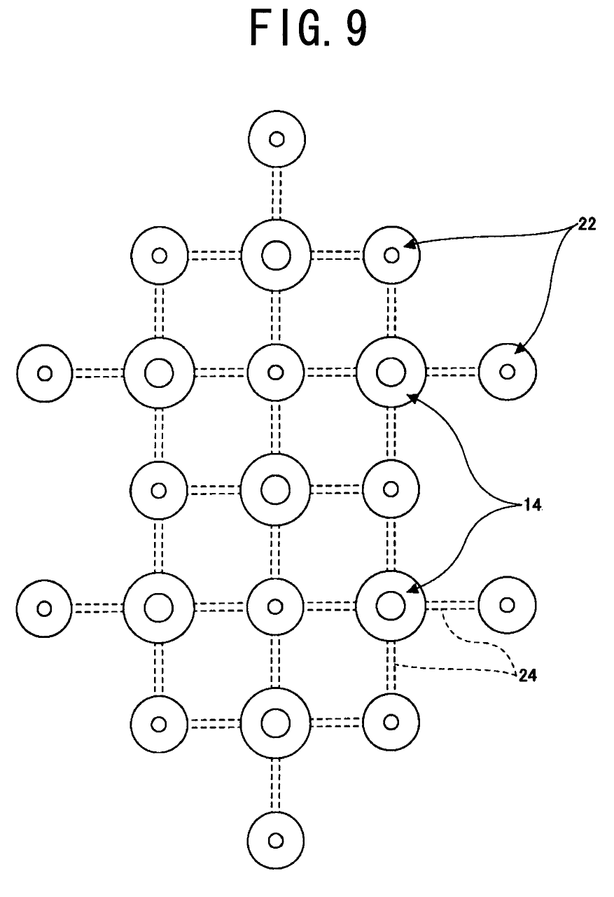

As shown in FIG. 9, one of the test plated through holes 22 can be commonly used for a plurality of the plated through holes 14. For example, the test plated through hole 22 allocated near the center is commonly used for the four of the surrounding plated through holes 14.

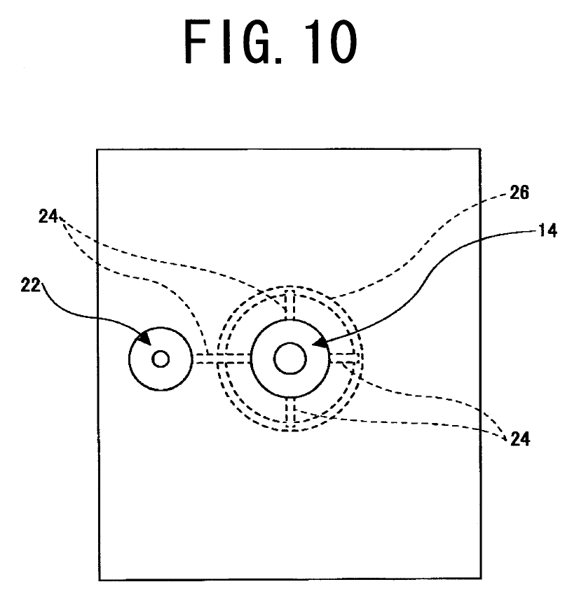

Next, a third embodiment is explained using FIG. 10.

Only one of the test plated through holes 22 is provided in the present embodiment. And, all of the test wiring patterns 24 connected from the four directions surrounding the plated through hole 14 are connected to the test plated through hole 22 through a test relay wiring pattern 26. The test wiring pattern 24 and the test relay wiring pattern 26 are both formed in the multi-layer wiring board 10a and are shown with dotted lines in FIG. 10.

In the present embodiment, the misalignments of the back-drilled hole 20 in the four directions connected by the test relay wiring pattern 26 can be determined by a tester test at only one time. If at least one of the test wiring patterns 24 extended in the four directions remains unremoved, it can be determined that a bad back-drill occurs because the test plated through hole 22 is electrically connected to the test relay wiring pattern 26 having an annulus ring shape. That is, the present embodiment can test the misalignments of the back-drilled hole 20 in a plurality of directions at one time.

The pattern of the test relay wiring pattern 26 is not limited to an annulus ring shape. A test relay wiring pattern in any pattern is applicable if all of the test wiring patterns 24 extended from the plated through hole 14 are connected to the test relay wiring pattern 26.

According to the present embodiment, the tester test can check all bad back-drills in the four directions at only one time. On the other hand, according to the first embodiment, the test is performed for the plated through hole 14 in each of the four directions, respectively. Thus, it is possible to determine in which direction a misalignment of the back-drilled hole 20 occurs.

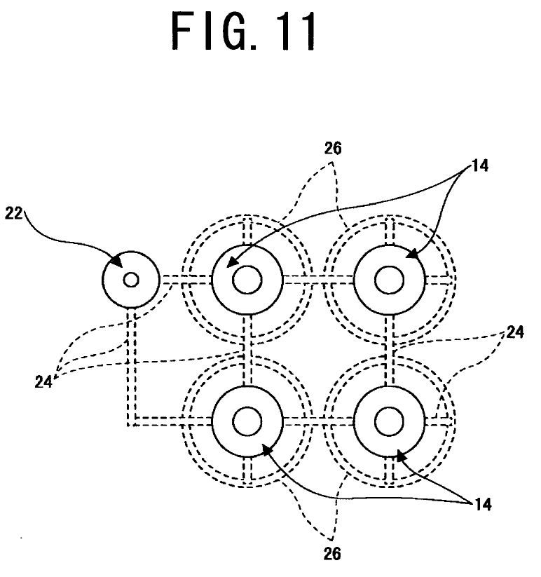

In FIG. 11, of the four plated through holes 14, the test relay wiring patterns 26 provided in the plated through hole 14 at right above is connected to the test relay wiring pattern 26 provided in the adjacent plated through hole 14 at left above. Also, the test relay wiring pattern 26 provided in the plated through hole 14 at lower right is connected to the test plated through hole 22. In the same way, the test relay wiring pattern 26 provided at lower right is connected to the test relay wiring pattern 26 provided in the plated through hole 14 at lower right, and the test relay wiring pattern 26 provided in the plated through hole 14 at lower left is connected to the test plated through hole 22.

According to the configuration described above, all of the test relay wiring patterns 26 provided in the four plated through holes 14 are electrically connected to one of the test plated through hole 22. For example, a test for the plated through hole 14 at right above is realized by checking the electrical continuity between the plated through hole 14 at right above and one of the test plated through hole 22. A test for the plated through hole 14 at lower left is realized by checking the electrical continuity between the plated through hole 14 at lower left and one of the test plated through hole 22.

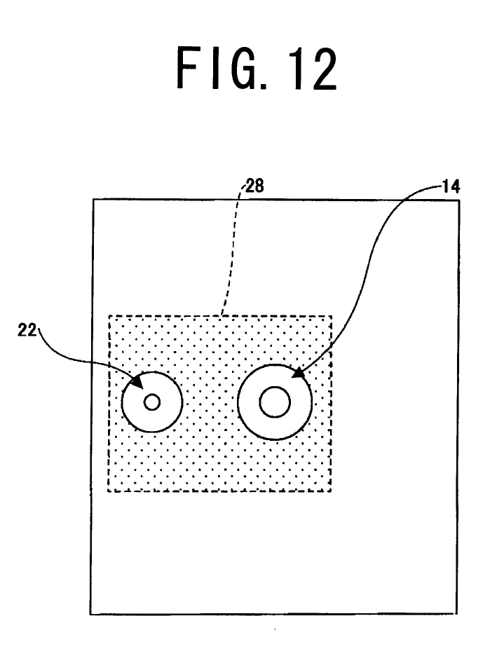

Next, a fourth embodiment is explained using FIG. 12.

In the present embodiment, the plated though hole 14 having a stub to remove is connected to the test plated through hole 22 in a test wiring pattern 28. The test wiring pattern 28 is a wiring pattern formed in the multi-layer wiring board 10a so as to entirely cover the areas including the plated through hole 14 and the test plated through hole 22.

The present embodiment corresponds to the configuration connected by the test wiring pattern 24 from all the directions of the plated through hole 14. Also, the present embodiment can determine whether or not a bad back-drill occurs in all the directions.

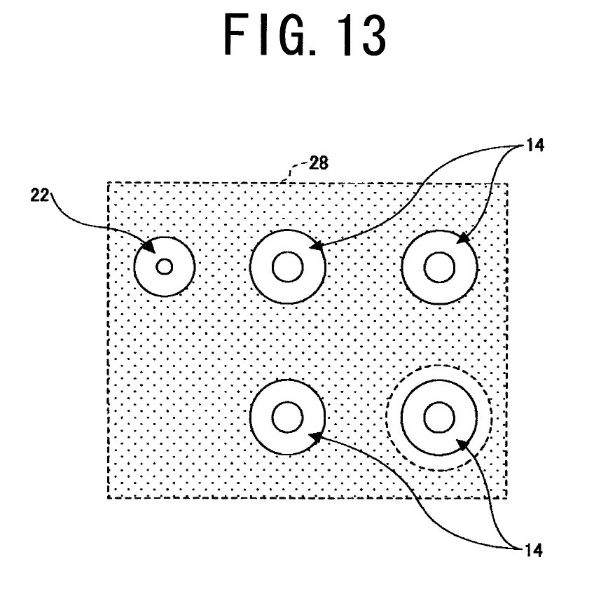

FIG. 13 discloses that the test wiring pattern 28 is provided and one of the test plated through holes 22 is commonly used for a plurality of the plated through holes 14. If there is a plated through hole 14 having no stub to remove in the areas covered by the test wiring pattern 28, the plated through hole 14 should be electrically separated from the test wiring pattern. For example, a plated through hole having no stub to remove may not be used as a signal path of high-frequency signals.

In FIG. 13, the plated through hole 14 at lower right discloses a plated through hole having no stub to remove.

According to the configuration shown in FIG. 13, of the four plated through holes 14, three of the plated through holes 14 excluding the plated through hole 14 at lower right are electrically connected to the test plated through hole 22. In the configuration described above, for example, a test of the plated through hole 14 at right above is realized by checking the electrical continuity between the plated through hole 14 at lower left and the test plated through hole 22. A test of the plated through hole 14 at lower left is realized by checking the electrical continuity between the plated through hole 14 and the test plated through hole 22.

The test wiring pattern 28 comprising the multi-layer wiring board 10a is a ground layer generally considered to be at ground potential, and is used for nothing other than a test of back drill.

What is claimed is:

1. A wiring board, comprising:
a plated through hole formed in the wiring board;
a test plated through hole or a test via hole provided in the surrounding area of the plated through hole to check a processing state related to the plated through hole; and
a conductive pattern used to electrically connect the plated through hole to the test through hole or the test via hole.

2. A wiring board, comprising:
a plated through hole formed in the wiring board;
a processing hole formed to remove a part of the plated through hole in the position where the plated through hole is provided;
a test plated through hole and a test via hole in the surrounding area of the test plated through hole to check a processing state related to the plated through hole; and
a conductive pattern extended between the processing hole where the plated through hole is removed and the test plated through hole or the via hole, and also is electrically connected to the test plated through hole or the test via hole.

3. The wiring board according to claim 2, wherein the processing hole is deeper than the distance from the surface of the processing hole to the conductive pattern.

4. The wiring board according to claim 2, wherein the conductive pattern includes a plurality of wiring patterns extended from a plurality of positions around the processing hole, and the test plated through hole or the test via hole is provided for each of the wiring patterns.

5. The wiring board according to claim 4, wherein four of the wiring patterns are provided equiangularly around the processing hole.

6. The wiring board according to claim 2, wherein the conductive pattern includes a plurality of wiring patterns extended from a plurality of positions around the processing hole, and a plurality of the wiring patterns are connected to the test plated through hole or the via hole.

7. The wiring board according to claim 6, wherein the conductive pattern further includes a relay wiring pattern connected by all of the wiring patterns, and the relay wiring pattern is connected to the test plated through hole or the test via hole.

8. The wiring board according to claim 7, wherein the relay wiring pattern has an annulus ring shape surrounding the processing hole.

9. The wiring board according to claim 2, wherein the conductive pattern includes a conductive layer formed in the board, and the conductive layer is formed in an area including the processing hole and the test plated through hole or the test via hole.

10. The wiring board according to claim 9, wherein the conductive layer is a ground layer considered to be at ground potential.

11. The wiring board according to claim 9, wherein the conductive layer is separated from the plated through hole in which the processing hole is not formed.

12. A method of manufacturing a wiring board, comprising:
forming a plated through hole in the wiring board;
forming a test plated through hole or a via hole in the wiring board;
forming a conductive pattern which is used to electrically connect the plated through hole to the test plated through hole or the test via hole; and
forming a processing hole in a position in the wiring board where the plated through hole is located.

13. The method of manufacturing the wiring board according to claim 12, wherein the forming the processing hole comprises
removing a part of the conductive pattern with a part of the plated through hole so that the plated through hole is electrically separated from the test plated through hole or the test via hole.

14. The method of manufacturing the wiring board according to claim 12, further comprising:
testing an electrical continuity between the plated through hole and the test plated through hole after the processing hole is formed; and
determining a quality of processing state of the processing hole based on the test result.

15. The method of manufacturing the wiring board according to claim 14, wherein the determining the quality of processing state of the processing hole comprises determining the quality of processing state to be good when there is no electrical continuity between the plated through hole and the test plated through hole or the test via hole after the processing hole is formed.
